(19) United States
(12) Patent Application Publication
(10) Pub. No.: US 2003/0052376 A1
(43) Pub. Date: Mar. 20, 2003

(54) Semiconductor device with high-k dielectric layer and method for manufacturing the same

(75) Inventors: Kee-Jeung Lee, Kyoungki-Do (KR); Su-Jin Chae, Kyoungki-Do (KR)

Correspondence Address: MARSHALL, GERSTEIN & BORUN, 6300 SEARS TOWER, 233 SOUTH WACKER, CHICAGO, IL, 60606-6357, US

(73) Assignee: HYNIX SEMICONDUCTOR INC., Kyoungki-Do (KR)

(21) Appl. No.: 10/241,939

(22) Filed: Sep. 12, 2002

(30) Foreign Application Priority Data
Sep. 14, 2001 (KR) 2001-56741

(51) Int. Cl. H01L 29/76

(52) U.S. Cl. 257/410

(57) ABSTRACT

Disclosed is a semiconductor device with high-k dielectric layer. The semiconductor device has a dielectric layer including a first dielectric layer containing aluminum and a second dielectric layer containing lithium in the first dielectric layer.

### BACKGROUND

1. Technical Field

A semiconductor device with high-k dielectric layer is disclosed.

2. Description of the Related Art

Generally, a SiO₂ layer, which is grown by a rapid thermally treatment process, has been used as a gate oxide layer in a DRAM or a logic device of a semiconductor device. As a design rule of the semiconductor device decreases, a tunneling effective thickness (Teff) has been reduced to a thickness of 25 Å to 30 Å, which is a tunneling limitation of the SiO₂ layer. An appropriate thickness of the SiO₂ layer is about 25 Å to 30 Å in a semiconductor device of a 0.1 μm size. However, since an off-current increases due to a direct tunneling, an operation of the semiconductor device is deteriorated. Specially, it is very important to reduce a leakage current in the memory device.

To solve the above problem, a high-k dielectric layer has been researched as the gate oxide layer. There are high-k dielectric materials, such as a Ta₂O₅ layer, which is used as a capacitor storage, a TiO₂ layer, an Al₂O₃ layer, a HfO₂ layer or the like.

Recently, as an integration of a memory device is rapidly accelerated due to a development of a fine semiconductor processing technology, an area of a unit cell in the semiconductor device is highly reduced and a low power is required as an operation power. However, a capacitance for an operation of the memory device is required over 25 fF/cell to protect a soft error and a reduction of a refresh time even if an area of the cell is reduced.

Accordingly, when a nitride layer having a NO (Nitride/Oxide) structure is used as a dielectric layer in a capacitor, a storage electrode having a 3-dimensional hemispherical structure, which has a large surface area, is usually used and the height thereof gradually increases. When a height of the capacitor increases, a desired focusing depth cannot be obtained in a post exposure process due to a difference between the cell of the capacitor and adjacent circuits in their height so that it causes a bad effect on an integration process. As mentioned above, a capacitor using a NO layer, as a dielectric layer, cannot be applied to a next generation memory device of over 256 Mb memory devices because it is difficult to obtain a desired capacitance.

As a semiconductor device is highly integrated, a high-k dielectric material, such as Ta₂O₅, TiO₂, TiO₂, SrTiO₃, (Ba, Sr)TiO or the like, is developed as a material of a dielectric layer in a capacitor instead of SiO₂, Si3N4 or NO.

Specially, a capacitance (∈) of the Ta₂O₅ layer, which ∈ is about 25 to 27, is much higher than that of a NO layer, which ∈ is about 4 to 5. Namely, the Ta₂O₅ layer is eligible for the dielectric layer in the capacitor.

FIG. 1 is a cross-sectional view showing a capacitor according to the prior art.

Referring to FIG. 1, a first electrode 11, which is a bottom electrode of a capacitor, is formed with a doped polysilicon layer and a dielectric layer 12 having a stacked structure, such as a SiO₂/Ta₂O₅ layer or a SiO₂/Ta₂O₅ layer, is formed on the first electrode 11. Sequentially, a second electrode 13 is formed with a polysilicon layer on the dielectric layer 12. Also, the dielectric layer 12 may be formed with a SiOₓN_{y}/Si₃N₄ layer or a SiOₓN_{y}/Ta₂O₅ instead of a SiO₂ layer.

The first and second electrodes 11 and 13 are formed with a doped polysilicon layer or a doped amorphous silicon layer. Also, the first and second electrodes 11 and 13 can be formed with metal materials, such as TiN, TaN, W, WN, WSi, Ru, RuO₂, Ir, IrO₂, Pt or the like. However, when a simply stacked structure is used in a capacitor, there is a limitation on increase in the cell's capacitance.

FIG. 2 is a cross-sectional view showing another capacitor according to the prior art.

Referring to FIG. 2, a first electrode 110, which is a bottom electrode of a capacitor, is formed with a polysilicon layer on a semiconductor substrate 100 and a dielectric layer 120 is formed to a stacked structure, such as a SiO₂/Si₃N₄ layer or a SiO₂/Ta₂O₅ layer, on the first electrode 110. Subsequently, a second electrode 130, which is a top electrode of a capacitor, is formed by a doped polysilicon layer on the dielectric layer 120. The first and second electrodes 110 and 130 are formed with a doped polysilicon layer or a doped amorphous silicon layer. Also, the first and second electrodes 110 and 130 can be formed with metal materials, such as TiN, TaN, W, WN, WSi, Ru, RuO₂, Ir, IrO₂, Pt or the like.

Also, the first electrode 110 can be formed in various 3-D structures, such as a cylinder structure. As a polysilicon layer 110A having hemispherical grains is employed, a surface area of the first electrode 110 increases.

The reference numeral 100 denoted in FIG. 2 represents a source/drain of a transistor or an interconnection layer including a plug to be connected the source/drain.

However, there is a limitation on enough capacitance of the SiO₂/Si₃N₄ (or SiOₓN_{y}/Si₃N₄) layer.

Since a Ta₂O₅ layer has an unstable stoichiometry, substitutional tantalum atoms occupying oxygen vacancies due to a difference of a composition ratio between tantalum and oxygen locally remain in the layer. The oxygen vacancies cannot be still removed. In addition, since the Ta₂O₅ layer has high oxidation reactivity with a polysilicon layer or a TiN layer, which is used as top/bottom electrodes, oxygen atoms are moved to a surface of the layer so that a low-k dielectric layer is formed or uniformity of a boundary is deteriorated.

Impurities, such as carbon atoms, carbon compound, H₂O or the like, which are generated by an reaction between a precursor Ta(OC₂H₅)₂ of the tantalum oxide layer and organics remain in the layer. A leakage current of the capacitor increase due to the impurities and a dielectric characteristic is deteriorated.

Accordingly, a low temperature thermal treatment process is needed for removing impurities that is less complex than those described above.

### SUMMARY OF THE DISCLOSURE

A manufacturing method and a semiconductor device are disclosed which provide a proper dielectric layer to prevent a leakage current characteristic and dielectric characteristic deterioration caused by remnant impurities within a layer.

A method and a semiconductor device are also disclosed for acquiring enough discharging capacity required in a high integration semiconductor device.

In an embodiment, a dielectric layer comprises: a first dielectric layer containing aluminum; and a second dielectric layer containing lithium formed on the first dielectric layer. The first dielectric layer is a Al₂O₃ layer and the second dielectric layer is a LiₓTa₁₋ₓO₃ layer (x=0.2 to 0.8).

In a second embodiment, a semiconductor device comprises: a semiconductor substrate; a first gate insulating layer containing aluminum in the semiconductor substrate; a second gate insulating layer containing lithium formed on the first gate insulating layer; and a gate electrode formed on the second gate insulating.

In a third embodiment, a method of manufacturing a semiconductor device comprises: forming first gate insulating layer containing aluminum on a semiconductor substrate; b) forming a second gate dielectric layer containing lithium on the first gate dielectric layer; and c) forming a gate electric on the second dielectric layer.

In a fourth embodiment, a capacitor comprises: a first electrode having an uneven surface on its surface; a first dielectric layer containing aluminum formed on the first electrode; a second dielectric layer containing lithium on the first dielectric layer; and a second electrode formed on the second dielectric layer.

In a fifth embodiment, a method of manufacturing a capacitor comprises: forming a first electrode; b) forming a first dielectric layer containing aluminum on the first electrode; c) forming a second dielectric layer containing lithium on the first dielectric layer; and d) forming a second electrode on the second dielectric layer.

In a sixth embodiment, a method of manufacturing a capacitor comprises: forming a first electrode; b) forming a unevenness on the first electrode; c) nitrating surface of the first electrode, where the unevenness is formed; d) forming an Al₂O₃ layer on the nitrated first electrode; e) applying thermal process to the Al₂O₃ layer; f) forming LiₓTa₁₋ₓO₃ layer, wherein x ranges from about 0.2 to about 0.8 on the thermal processed Al₂O₃ layer; g) applying thermal process to the LiₓTa₁₋ₓO₃ layer; and h) forming a second electrode on the thermal processed LiₓTa₁₋ₓO₃ layer.

### BRIEF DESCRIPTION OF THE DRAWINGS

The above and other features of the disclosed devices and methods will become apparent from the following description of the preferred embodiments taken in conjunction with the accompanying drawings, wherein:

FIG. 1 is a cross-sectional view illustrating a stacked-type capacitor according to the prior art;

FIG. 2 is a cross-sectional view illustrating a cylinder-type capacitor according to the prior art;

FIG. 3 is a cross-sectional view illustrating a semiconductor device having an Al₂O₃/LiTaO₃ layer as a dielectric layer according to the disclosure;

FIG. 4 is a flow chart illustrating a method for fabricating the semiconductor device in FIG. 3 according to the disclosure;

FIG. 5 is a cross-sectional view illustrating a capacitor having a stacked Al₂O₃/LiTaO₃ layer in the semiconductor device according to the disclosure;

FIG. 6 is a cross-sectional view illustrating another capacitor having a stacked Al₂O₃/LiTaO₃ layer in the semiconductor device according to the disclosure;

FIG. 7 is a cross-sectional view illustrating a cylinder-type capacitor having a stacked Al₂O₃/LiTaO₃ layer in the semiconductor device according to the disclosure;

FIG. 8 is a cross-sectional view illustrating another cylinder-type capacitor having a stacked Al₂O₃/LiTaO₃ layer in the semiconductor device according to the disclosure; and

FIG. 9 is a flow chart showing a method for fabricating a capacitor according to the second and third embodiments of the disclosure.

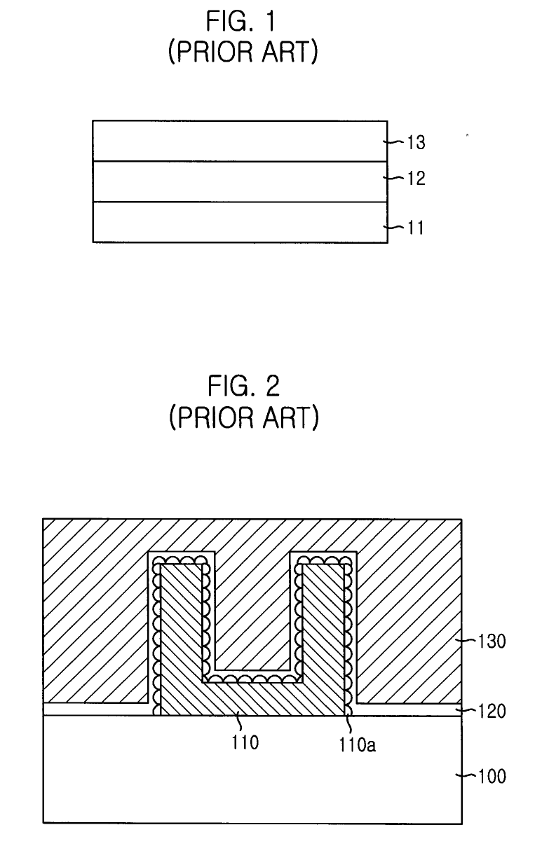

### DETAILED DESCRIPTION OF THE PRESENTLY PREFERRED EMBODIMENTS

Hereinafter, a semiconductor device having a stacked dielectric layer will be described in detail referring to the accompanying drawings.

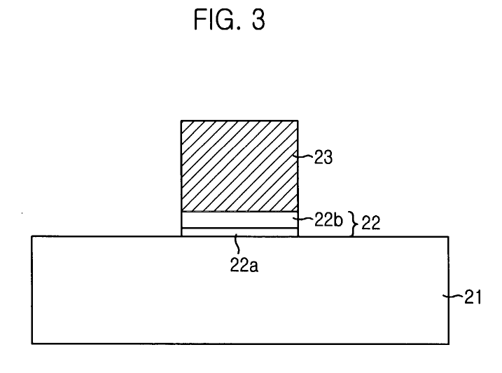

FIG. 3 is a cross-sectional view showing a semiconductor device having an Al₂O₃/LiTaO₃ layer as a dielectric layer.

Referring to FIG. 3, the semiconductor device includes a semiconductor substrate 21, a gate oxide layer 22 and a gate electrode 23 formed on the gate oxide layer 22.

The gate oxide layer 22 has a first oxide layer 22a containing an aluminum material and a second oxide layer 22b of high dielectric constants are stacked, wherein the second gate oxide layer 22b containing a lithium material.

The first oxide layer 22a is an Al₂O₃ layer, of which a dielectric constant is 7, having a perovskite structure and a covalent bonding. The second oxide layer 22b is formed with LiₓTa₁₋ₓO₃ layer (x=0.2 to 0.8), of which the dielectric constant is 45.

A thickness of the first oxide layer 22a is thinner than that of the second oxide layer 22b. The first oxide layer 22a is formed at a thickness ranging from about 10 Å to about 20 Å and the second gate oxide layer 22b is formed at a thickness ranging from about 50 Å to about 100 Å. The first oxide layer 22a is an oxygen diffusion barrier layer which prevents oxygen diffusion from the second oxide layer 22b into the semiconductor substrate 21 and also prevents a low-k dielectric layer from being formed on the surface of the semiconductor substrate 21.

The semiconductor substrate 21 is a normal silicon substrate and a gate electrode 23 is formed with a material selected from a group consisting of a silicon material including doped polysilicon and doped amorphous silicon, a metal material including TiN, TaN, W, WN, Ru, Rr or Pt, a metal oxide material including RuO₂ or IrO₂, and a silicide material including WSi, which are used as a material of a gate electrode of a transistor.

When the gate electrode 23 is formed with a TiN layer, a doped polysilicon layer can be deposited as a buffer layer to improve durability of the TiN layer against a thermal or electrical impact and obtain structural stability.

A nitride layer may be formed between the first electrode 22a and the semiconductor substrate 21 to suppress a formation of a low-k dielectric layer.

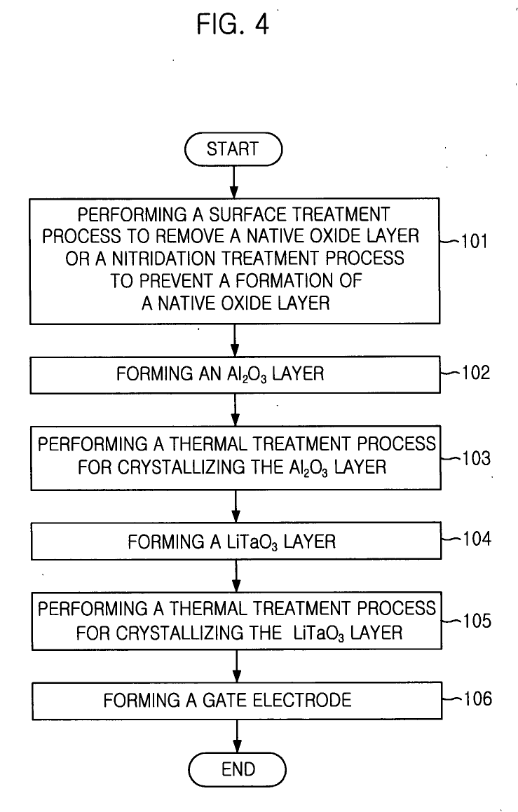

FIG. 4 is a flow chart showing a method for fabricating the semiconductor device in FIG. 3.

Referring to FIG. 4, a surface treatment process is carried out to remove a native oxide (SiO₂) layer generated on the surface of the semiconductor substrate 21 or a nitration process is carried out to prevent a generation of the native oxide layer and to minimize a formation of a low-k dielectric layer generated in a post Al₂O₃ layer deposition process at a step 101.

The surface treatment process is carried out in-situ or ex-situ by using a HF gas, a HF solution or the like. Before or after the HF surface treatment process in the surface treatment process of the substrate, a cleaning process is carried out or a surface treatment using a NH₄OH solution or a H₂SO4 solution is carried out to improve uniformity of the surface thereof.

The nitration process is carried out in-situ or exsitu by a plasma discharge in an atmosphere of a NH₃ gas or a N₂/H₂ gas at a low pressure chemical vapor deposition (LPCVD) chamber. At this time, a wafer is maintained at a temperature ranging from about 300° C. to about 500° C.

Another nitration process is carried out in-situ or ex-situ by a rapid thermal nitration process using a rapid thermal process at a temperature ranging from about 750° C. to about 950° C. and in an atmosphere of a NH₃ gas for a time period ranging from about 30 seconds to about 120 seconds. Also, the nitration process can be carried out by using an electro-furnace process at a temperature ranging from about 500° C. to about 1000° C. and in an atmosphere of a NH₃ gas.

The first oxide layer 22a is formed on the semiconductor substrate 21, which the surface treatment process or the nitration process is completed, at a thickness ranging from about 10 Å to about 30 Å with an Al₂O₃ layer. A chemical vapor having aluminum is provided into a vaporizer or an evaporation tube through a flow controller, such as a MFC, and an oxygen (O₂) gas is added.

Next, a thermal treatment is carried out by using an in-situ plasma in an atmosphere of a NO₂ gas or a O₂ gas and at a temperature ranging from about 200° C. to about 600° C. to remove structural defects caused by dangling bonds and to improve a structural non-homogeneity so that a leakage current is reduced.

After depositing a LiTaO₃ layer, a crystallization process of the Al₂O₃ layer to play a role of a diffusion barrier layer is carried out at a temperature ranging from about 800° C. to about 950° C. and in an atmosphere of a N₂ gas or a N₂/O₂ gas in a rapid thermal process chamber to protect an oxygen diffusion into a semiconductor substrate 21 at step S103.

Also, the crystallization process of the Al₂O₃ layer can be carried out by using an electro-furnace at a temperature ranging from about 700° C. to about 800° C. and in an atmosphere of a N₂O gas, a N₂ gas or N₂/O₂ gas for a time period ranging from about 10 minutes to about 30 minutes.

Next, after forming the LiTaO₃ layer on a crystallized Al₂O₃ layer using the LPCVD or ALD depositing method at step S104, a high thermal treatment to induce crystallization of the LiTaO₃ layer is carried out at step S105.

For example, the LPCVD method for the LiTaO₃ layer is performed within a low pressure chemical vapor deposition chamber (hereinafter, referred to as a LPCVD chamber), which is maintained at a temperature ranging from about 300° C. to about 600° C. and at a pressure ranging from about 0.1 to about 5.0 torr. A chemical vapor with Li element and a vapor gas with Ta compound are injected into the chamber with a mole ratio of Ta/Li ranging from about 0.1 to about 10 mole ratio together with a reactive oxygen (O₂) gas flow rate ranging from about 0 sccm to about 300 sccm and there are provided as much as predetermined amount through a mass flow controller (MFC). As a result, the amorphous LiTaO₃ layer is formed at a thickness ranging from about 50 Å to about 100 Å by a surface chemical reaction generated in a wafer.

In here, the Li compound chemical vapor is obtained by melting Li compound, such as C₂H₃LiO₂, LiOH and Li₂O, in alcohol, such as ethanol or butanol, or a distillated liquid and then by making a saturated liquid or over-saturated liquid. The Li elements are obtained after providing the liquid to a vaporizer (or an evaporation tube), through a liquid controller, such as MFC, and then a predetermined amount is vaporized at a temperature ranging from about 100° C. to about 400° C.

The Ta bearing vapor gas is generated by evaporating organic metal compound having Ta(OC₂H₅)₅ or Ta(N(CH₃)₂)₅ of over 99.999% provided through a MFC in the vaporizer or the evaporation tube maintained at a temperature ranging from about 150° C. to about 200° C. To protect condensation of the vapor gas, a temperature is maintained ranging from about 150° C. to about 200° C. and at a pressure ranging from about 0.1 torr to about 5 torr.

At the time of depositing the above-mentioned LiTaO₃ layer, the Li compound, such as C₂H₃LiO₂, LiOH and Li₂O, which are may be used as a precursor of Li have a strong absorption of carbon oxide and hydrate, so an additionally generated impurities may be effectively absorbed through a surface chemical reaction.

Next, the thermal treatment process for crystallizing an amorphous LiTaO₃ layer is carried out in the rapid thermal process chamber at a temperature ranging from about 800° C. to about 950° C. and in an atmosphere of a N₂O gas, a N₂ gas or a N₂/O₂ gas for a time period ranging from about 30 seconds to about 120 seconds. As crystallizing an amorphous LiTaO₃ layer, a capacitance increases. At this time, impurities, for example, a carbon oxide remaining in the LiTaO₃ layer, are completely removed with the formation of by-product, such as CO, CO₂, H₂O, CH₄ and C₂H₄.

Also, the thermal treatment process for crystallizing the amorphous LiTaO₃ layer can be carried out in the electro-furnace at a temperature ranging from about 700° C. to about 800° C. and in an atmosphere of a N₂O gas, or a O₂ gas for a time period ranging from about 10 minutes to about 30 minutes.

At step S106, a gate electrode 23 is formed on the LiTaO₃ layer. The gate electrode 23 can be formed using the LPCVD technique, the plasma enhanced CVD (PECVD) technique or the RF-magnetic sputtering (RF-MS) technique.

In the above-mentioned first embodiment, since the Al₂O₃ layer is formed on the semiconductor substrate, a diffusion of the LiTaO₃ layer having a high dielectric constant is protected and then the Al₂O₃ layer prevent the LiTaO₃ layer from being transformed into a SiO₂ layer having a low dielectric constant.

Since the Al₂O₃ layer has a perovskite structure, high breakdown voltage is expected due to a high mechanical strength and, since the LiTaO₃ layer has a high dielectric constant, a sufficient capacitance can be obtained.

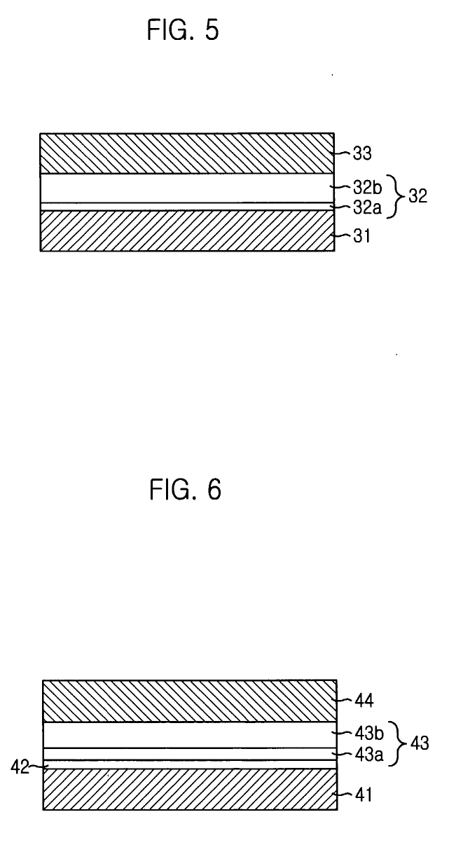

FIG. 5 is a cross-sectional view showing a capacitor having a stacked Al₂O₃/LiTaO₃ layer in the semiconductor device.

Referring to FIG. 5, a first electrode 31, a dielectric layer 32 and a second electrode 33 are sequentially formed. The dielectric layer 32 is formed to a stacked layer having a first dielectric layer 32a having a high mechanical strength and a second dielectric layer having a high dielectric constant.

The first dielectric layer 32a is formed to an Al₂O₃ layer, which has a dielectric constant is 7, a perovskite structure and a covalent bonding. The second dielectric layer 32b is formed with a layer, which has a dielectric constant is 7, and having a LiₓTa₁₋ₓO₃ layer (x=0.2 to 0.8) with perovskite.

A thickness of the first dielectric layer 32a is thinner than that of the second dielectric layer 32b. The first dielectric layer 32a is formed at a thickness ranging from about 10 Å to about 20 Å and the second dielectric layer 32b is formed at a thickness ranging from about 50 Å to about 100 Å.

The first electrode 31, which is a bottom electrode, and the second electrode 33, which is a top electrode, are formed with a silicon layer having at least a doped polysilicon layer or a doped amorphous silicon layer, a metal layer having at least TiN, TaN, W, WN, Ru, Ir or Pt or a silicide layer having at least CoSi, MoSi or WSi.

When a TiN layer is formed as the second electrode 33, a doped polysilicon layer can be formed as a buffer layer to improve a resistance of the TiN layer against an electrical and thermal impacts.

FIG. 6 is a cross-sectional view showing another capacitor having a stacked Al₂O₃/LiTaO₃ layer in the semiconductor device.

Referring to FIG. 6, a first electrode 41, a dielectric layer 43 and a second electrode 44 are sequentially formed.

The dielectric layer 43 is formed to a stacked layer having a first dielectric layer 43a having a mechanical strength and a second dielectric layer 43b having a high dielectric constant. A nitride containing layer 42 is formed by a nitration process of a boundary between the first electrode 41 and the dielectric layer 43.

The first dielectric layer 43A is formed to an Al₂O₃ layer, which has a dielectric constant is 7, a perovskite structure and a covalent bonding. The second dielectric layer 43b is formed in a LiₓTa₁₋ₓO₃ layer (x=0.2 to 0.8), which has a dielectric constant is 45.

A thickness of the first dielectric layer 43a is thinner than that of the second dielectric layer 44b. The first dielectric layer 43a is formed at a thickness ranging from about 0 Å to about 20 Å and the second dielectric layer 43b is formed at a thickness ranging from about 50 Å to about 100 Å.

The first electrode 41, which is a bottom electrode, and the second electrode 44, which is a top electrode, are formed with a silicon layer having at least a doped polysilicon layer or a doped amorphous silicon layer, a metal layer having at least TiN, TaN, W, WN, Ru, Ir or Pt or a silicide layer having at least CoSi, MoSi or WSi.

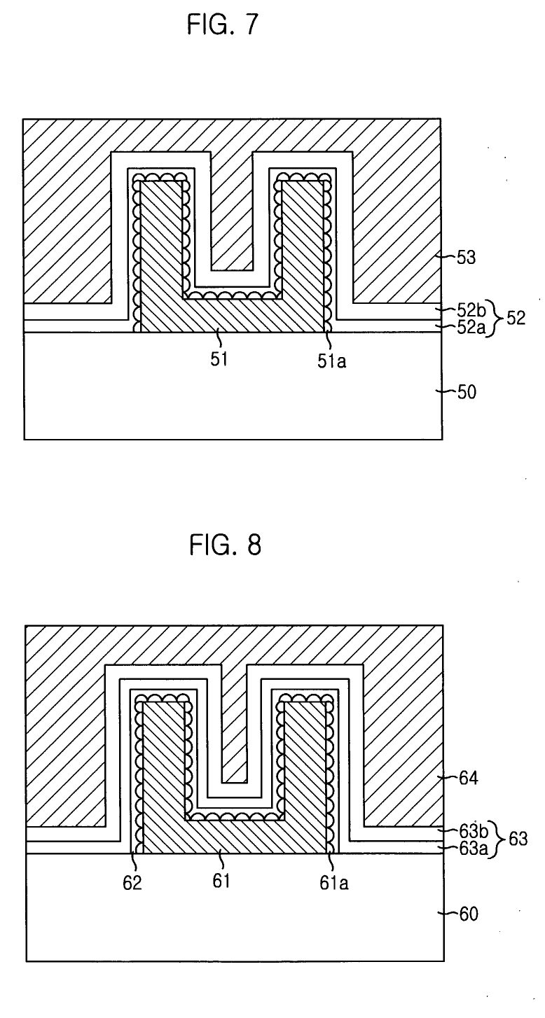

FIG. 7 is a cross-sectional view showing a cylinder-type capacitor having a stacked Al₂O₃/LiTaO₃ layer in the semiconductor device.

Referring to FIG. 7, an interconnection layer 50 including a source/drain of a transistor and plug is formed.

A cylinder-type first electrode 51 having unevenness 51a is formed on the interconnection layer 50. A dielectric layer 52, which is a stacked structure, is formed over the first electrode 51 and a second electrode 53 is formed on the dielectric layer 52. The dielectric layer 52 is formed to a stacked layer including a first dielectric layer 52a having a high mechanical strength and a second dielectric layer 52b having a high dielectric constant.

The first dielectric layer 52a is formed to an Al₂O₃ layer, which has a dielectric constant of 7, a perovskite structure and a covalent bonding. The second dielectric layer 32B is formed to a LiₓTa₁₋ₓO₃ layer (x=0.2 to 0.8), which has a dielectric constant of 45.

A thickness of the first dielectric layer 52a is thinner than that of the second dielectric layer 52b. The first dielectric layer 52a is formed at a thickness ranging from about 10 Å to about 20 Å and the second dielectric layer 52b is formed at a thickness ranging from about 50 Å to about 100 Å.

The first electrode 51, which is a bottom electrode, and the second electrode 53, which is a top electrode, are formed with a silicon layer having at least a doped polysilicon layer or a doped amorphous silicon layer, a metal layer having at least TiN, TaN, W, WN, Ru, Ir or Pt or a silicide layer having at least CoSi, MoSi or WSi.

When a TiN layer is formed as the second electrode 53, a doped polysilicon layer is deposited as a buffer layer to obtain a stability of a structure on the TiN layer to improve a resistance against thermal and electrical impacts.

The first electrode 51 can be formed to various 3-D structures based on a cylindrical structure. As adding unevenness 51a, such as hemispherical grains, to the first electrode 51, a surface area increases so that a desired capacitance can be obtained.

FIG. 8 is a cross-sectional view showing another cylinder-type capacitor having a stacked Al₂O₃/LiTaO₃ layer in the semiconductor device.

Referring to FIG. 8, an interconnection layer 60 including a source/drain of a transistor and plug is formed on a semiconductor substrate (not shown). A cylinder-type first electrode 61 having unevenness 61a is formed on the interconnection layer 60. A dielectric layer 63, which is a stacked structure, is formed over the first electrode 61 and a second electrode 64 is formed on the dielectric layer 63. The dielectric layer 63 is formed to a stacked layer including a first dielectric layer 63a having a high mechanical strength and a second dielectric layer 63b having a high dielectric constant.

In here, a nitride containing layer is formed by a nitration process of a boundary between the first electrode 61 and the dielectric layer 63.

The nitride containing layer 62 prevents a formation of a native oxide layer on a surface of the first electrode 61 and plays a role of an oxygen diffusion barrier layer by minimizing a formation of a low-k dielectric oxide layer at a boundary between the first electrode 61 and the dielectric layer 63 in a deposition process of the dielectric layer 62.

The first dielectric layer 63a is formed to an Al₂O₃ layer, which has a dielectric constant of 7, a perovskite structure and a covalent bonding. The second dielectric layer 63b is formed with a LiₓTa₁₋ₓO₃ layer (x=0.2 to 0.8), which has a dielectric constant of 45

A thickness of the first dielectric layer 63a is thinner than that of the second dielectric layer 63b. The first dielectric layer 63a is formed at a thickness ranging from about 10 Å to about 20 Å and the second dielectric layer 63b is formed at a thickness ranging from about 50 Å to about 100 Å.

The first electrode 61, which is a bottom electrode, and the second electrode 64, which is a top electrode, are formed with a silicon layer having at least a doped polysilicon layer or a doped amorphous silicon layer, a metal layer having at least TiN, TaN, W, WN, Ru, Ir or Pt or a silicide layer having at least RuO₂ and IrO₂, which are contained with WSi.

When a TiN layer is formed as the second electrode 64, a doped polysilicon is deposited as a buffer layer to obtain a stability of a structure on the TiN layer to improve a resistance against thermal and electrical impacts.

The first electrode 61 can be formed to various 3-D structures based on a cylinder structure. As adding unevenness 61a, such as hemispherical grains, to the first electrode 61, a surface area increases so that a desired capacitance can be obtained.

In the above-mentioned first and second embodiments, the Al₂O₃/LiTaO₃ layer, which is the first dielectric layer 63a, is a stable crystallized layer having a perovskite structure and a covalent bonding. Since the Al₂O₃/ LiTaO₃ layer plays role of diffusion barrier layer protecting that the Al₂O₃ layer is diffused into a lower layer through the LiTaO₃ layer in a thermal treatment process of a post LiTaO₃ layer, so that a formation of a low-k dielectric oxide layer on a boundary of the first electrode 61 can be prevented.

Specially, as the nitride layer is formed between the first electrode 61 and the dielectric layer 63, a formation of low-k dielectric oxide layer due to oxygen diffusion is prevented.

Also, a second dielectric layer having a high-k dielectric layer and a first dielectric layer preventing a low-k oxide layer formation is provided, so that an effective oxide thickness (Tox) is obtained below a thickness of 30 Å, thereby an amount of discharging is sufficiently obtained and a leakage current characteristic is excellent.

Especially, a first dielectric layer, which prevents formation of a second dielectric layer having a high-k dielectric constant and a first dielectric layer formation of a low-k oxide layer is provided. At the same time, a unevenness is also provided, so in the third embodiment of the disclosure, a capacitor discharging amount is more bigger than that of the first and the second embodiments of the disclosure.

According to the third embodiment of the disclosure, the cylinder-type capacitor is used. Also, a concave-type (uneven surface) capacitor can be used to obtain the same effects.

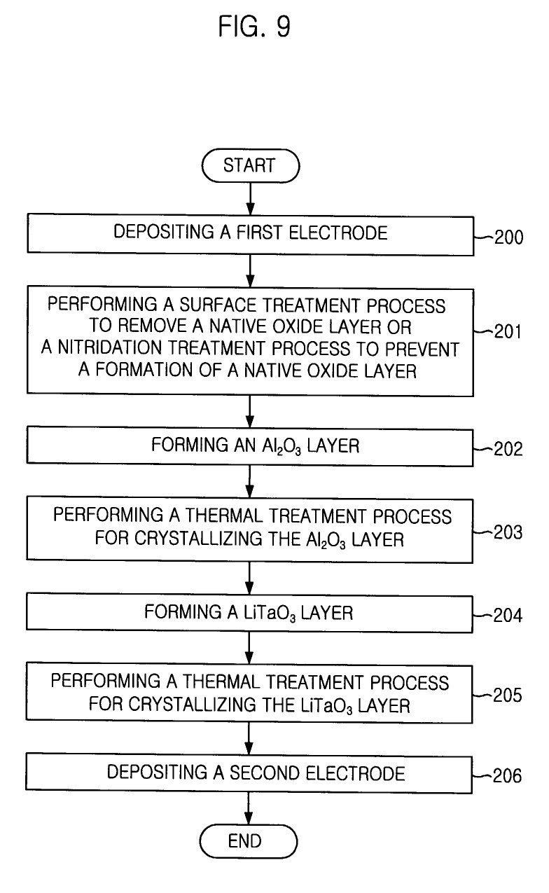

FIG. 9 is a flow chart showing a method for fabricating a capacitor according to the second and third embodiments of the disclosure.

A doped polysilicon layer is used as the first and second electrodes. The Al₂O₃ layer is used as a first dielectric layer and the LiTaO₃ layer is used as a second dielectric layer. A polysilicon layer having hemispherical grains (HSG) is formed on the surface of the first electrode. (not shown)

At step S200, after a doped polysilicon layer is deposited as the first electrode, a surface treatment process of the surface of the polysilicon layer is carried out to remove a native oxide (SiO₂) layer or a nitrating process is carried out to minimize a formation of a low-k dielectric oxide layer generated in an Al₂O₃ layer deposition process at step S201.

The surface treatment process is carried out in-situ or ex-situ by using a HF gas or a HF solution, and a boundary cleaning process is carried out before or after the HF surface treatment process. Also, a boundary treatment process can be carried out by using a NH₄OH solution or a H₂SO₄ solution to improve uniformity.

The nitration process is carried out by discharging a plasma in-situ or ex-situ in an atmosphere of a NH₃ gas or a N₂/H₂ gas in a low pressure chemical vapor deposition (LPCVD) chamber. At this time, a temperature of a wafer is maintained in a range from about 300° C. to about 500° C.

Another nitration process is carried out in-situ or ex-situ using a rapid thermal process (RTP) at a temperature ranging from about 750° C. to about 950° C. and at a NH₃ gas atmosphere for a time period ranging from about 30 seconds to about 120 seconds. Also, the nitration process can be carried out at an electro-furnace at a temperature ranging from about 500° C. to about 1000° C. and at a NH₃ gas atmosphere.

At step S202, the Al₂O₃ layer is formed on the doped polysilicon layer, which the surface treatment process or the nitration process is completed, as a dielectric layer of a capacitor. The Al₂O₃ layer is obtained by evaporating an Al(OC₂H₅)₃ solution, which is provided to a vaporizer or a evaporation tube through a flow controller, such as a MFC or the like, at a temperature ranging from about 150° C. to about 300° C. At this time, an oxygen gas is added.

Before performing the Al₂O₃ layer deposition, a thermal treatment process is carried out to improve structural defects and structural non-homogeneity at a temperature ranging from about 200° C. to about 600° C., in an NO₂ or an O₂ gas atmosphere, due to a dangling bond so that a leakage current characteristic is improved.

At step S203, before depositing the LiTaO₃ layer, a thermal treatment process for crystallizing the Al₂O₃ layer is carried out at a temperature ranging from about 800° C. to about 950° C. and in an atmosphere of an N₂ gas or an O₂ gas for a time period ranging from about 30 seconds to about 120 seconds in a rapid thermal process (RTP) device to play a role of a diffusion barrier layer protecting that oxidants are diffused into the doped polysilicon layer during a high thermal process.

Another thermal treatment process for crystallizing the Al₂O₃ layer is carried out at an electro-furnace at a temperature ranging from about 700° C. to about 800° C. and in an atmosphere of a N₂O gas or an O₂ gas for a time period ranging from about 10 minutes to about 30 minutes.

At step S204, the LiTaO₃ layer is formed by the LPCVD method or the atomic layer deposition (ALD) technique on the crystallized Al₂O₃ layer, and then at step S205, a thermal treatment is carried out for crystallizing the LiTaO₃ layer.

For example, the LiTaO₃ layer is formed by the LPCVD technique, a Ta bearing vapor gas and a reaction gas, an over O₂ gas at a pressure ranging from about 0 sccm to about 300 sccm, are injected through a MFC on a wafer in the low pressure chemical vapor deposition chamber maintained at a temperature ranging from about 300° C. to about 600° C. and at a pressure ranging from about 0.1 torr to about 5.0 torr and then the LiTaO₃ layer is formed by a surface chemical reaction at a thickness ranging from about 50 Å to about 100 Å with Ta/Li mole ratio ranging from about 0.1 to about 10.0 mole ratio.

In here, the Li compound of chemical vapor is obtained through a saturated solution or an over-saturated solution melting Li chemical compounds, such as C₂H₃LiO₂, LiOH and Li₂O, with an alcohol, i.e., an ethanol or a butanol, or a distillated liquid, are provided into a vaporizer (or an evaporation tube) using a flow controller, then a predetermined amount is vaporized at a temperature ranging from about 100° C. to about 400° C.

The Ta bearing vapor gas is generated by evaporating an organic metal compound having Ta(OC₂H₅)₅ or Ta(N(CH₃)₂)₅ of over 99.999% at a temperature ranging from about 150° C. to about 200° C. injected through a flow controller, such as a MFC. In order to prevent a condensation of the vapor gas, the vapor is injected to a LPCVD chamber maintained at a temperature ranging from about 150° C. to about 200° C. and at a pressure ranging from about 0.1 torr to about 5.0 torr and then the LiTaO₃ layer is deposited.

When depositing the above-mentioned LiTaO₃ layer depositing, Li chemical compounds, such as C₂H₃LiO₂, LiOH and Li₂O materials, which may be used as precursors of the Li chemical compounds, have strong absorption to a carbon oxide material and a hydrate, so they effectively absorb impurities additionally generated through a surface chemical reaction.

The thermal treatment process for crystallizing the amorphous LiTaO₃ layer is carried out at a temperature ranging from about 800° C. to about 950° C. and in an atmosphere of a N₂O gas, a N₂ gas or a N₂/O₂ gas for a time period ranging from about 30 seconds to about 120 seconds in the rapid thermal process (RTP) device. At this time, impurities, such as carbon compounds are completely removed in a form of CO, CO₂, H₂O, CH₄ and C₂H₄.

Also, another thermal treatment process for crystallizing the amorphous LiTaO₃ layer can be carried out at a temperature ranging from about 700° C. to about 800° C. and in an atmosphere of a N₂O gas-or an O₂ gas for a time period ranging from about 10 minutes to about 30 minutes in an electro-furnace.

At step S206, a doped polysilicon layer is deposited on the LiTaO₃ layer as a top electrode. The first and second electrodes are formed using the LPCVD method, the plasma enhanced chemical vapor deposition method or the RF-MS method.

As above-mentioned, when the Al₂O₃/LiTaO₃ capacitor is formed, thermal treatment processes of a low temperature, such as an in-situ or ex-situ N₂O or O₂ plasma thermal treatment process or an ex-situ UV—O₃ thermal process, which are required in a deposition process of a Ta₂O₅ layer, are not needed.

An extra thermal treatment process to oxidize substitutional Ta atoms remaining in the layer is not required to protect a leakage current by stabilize an unstable stoichiometry of the Ta₂O₅ layer.

The Al₂O₃ layer has a perovskite structure of an excellent mechanical and electrical strength. Breakdown voltage of the LiTaO₃ layer is higher than that of the Ta₂O₅ layer. In addition, since the LiTaO₃ layer has a stable Ta—O—N structure, the LiTaO₃ layer is strong against an external electrical impact.

When the stacked dielectric layer of the Al₂O₃/LiTaO₃ layer is used, the breakdown voltage increases and a leakage current level decreases rather than a capacitor, which uses one dielectric layer, such as NO, Al₂O₃, TaON or Ta₂O₅ layers.

As the Al₂O₃ layer having an excellent-oxidant is formed before depositing the LiTaO₃ layer, a formation of a low-k dielectric layer usually generated between the bottom electrode and the LiTaO₃ layer can be prevented so that an increase of a leakage current can be suppressed.

The present disclosure suppresses a low-k oxide layer formation in a boundary of a bottom electrode and a dielectric layer so, a thickness of an effective oxide layer (Tox) decreases compared with that of a NO layer, which Tox ranges from about 45 Å to about 55 Å and that of a Ta₂O₅ layer, which Tox ranges from about 30 Å to about 40 Å so that a sufficient capacitance can be obtained over 25 fF/cell even if a unit cell area is decreased due to a high integration of the semiconductor device.

Even though, if a capacitor module formation process is a simple stack structure, an enough amount of discharge may be obtained, so a complicated double or triple structure of capacitor module is not necessary to increase bottom electrode area, to thereby, a number of unit processing is rare and a period of unit process is short, to thereby a production cost is reduced.

When Al₂O₃/LiTaO₃ layers are used as a dielectric layer, it is more efficient than that of a capacitor and a gate oxide layer in using NO or Ta₂O₅layer as a dielectric layer, in that the former is stronger than electric impact applied from outside so a breakdown voltage is higher than that of NO or Ta₂O₅layer and leakage current level is lower.

Also, in a method of semiconductor device including a capacitor adapting Al₂O₃/LiTaO₃ layers, there is not required a low thermal treatment process, so that a number of unit process is reduced, and a period of production is short, thereby decreasing a production cost. Whereas, in a Ta₂O₅ layer formation process, a low thermal treatment process is needed through an amorphous Ta₂O₅, an in-situ or ex-situ N₂O or O₂ plasma thermal treatment and an ex-situ UV—O₃ thermal process.

Although the preferred embodiments have been disclosed for illustrative purposes, those skilled in the art will appreciate that various modifications, additions and substitutions are possible, without departing from the scope and spirit of the disclosure.

What is claimed is:

1. A dielectric layer comprising:
a first dielectric layer comprising aluminum; and
a second dielectric layer comprising lithium formed on the first dielectric layer.

2. The dielectric layer of claim 1, wherein the first dielectric layer is an Al₂O₃ layer.

3. The dielectric layer of claim 1, wherein the second dielectric layer is a LiₓTa₁₋ₓO₃ layer, wherein x ranges from about 0.2 to about 0.8.

4. A semiconductor device comprising:
a semiconductor substrate;
a first gate insulating layer comprising aluminum in the semiconductor substrate;
a second gate insulating layer comprising lithium formed on the first gate insulating layer; and
a gate electrode formed on the second gate insulating layer.

5. The semiconductor device of claim 4, wherein the first gate insulating layer is an Al₂O₃ layer

6. The semiconductor device of claim 4, wherein the second gate insulating layer is a LiₓTa₁₋ₓO₃ layer, wherein x ranges from about 0.2 to about 0.8.

7. The semiconductor device of claim 4, wherein the first and second gate electrodes are selected from the group consisting of a doped polysilicon layer, a doped amorphous silicon layer, a metal layer comprising one of TiN, TaN, W, WN, Ru, Ir and Pt, and a silicide layer comprising one of CoSi, MoSi and WSi.

8. The semiconductor of claim 4, further comprising a nitrogen containing layer provided between the semiconductor substrate and the first gate insulating layer.

9. The semiconductor device of claim 4, wherein the first gate insulating layer is formed at a thickness ranging from about 10 Å to about 20 Å.

10. The semiconductor device of claim 4, wherein the second gate insulating layer is formed at a thickness ranging from about 50 Å to about 100 Å.

11. A capacitor comprising:
a first electrode having an uneven surface on its surface;
a first dielectric layer comprising aluminum formed on the first electrode;
a second dielectric layer comprising lithium formed on the first dielectric layer; and
a second electrode formed on the second dielectric layer.

12. The capacitor of claim 11, wherein the first dielectric layer is an Al₂O₃ layer and wherein the second dielectric layer is a LiₓTa₁₋ₓO₃ layer, wherein x ranges from about 0.2 to about 0.8.

13. Method of manufacturing a semiconductor device comprising:
a) forming a first gate insulating layer comprising aluminum on a semiconductor substrate;
b) forming a second gate insulating layer comprising lithium on the first gate insulating layer; and
c) forming a gate electrode on the second gate insulating layer.

14. The method of claim 13, further comprising the step of performing a thermal treatment process of the first and second gate insulating layers after forming the first and second gate insulating layers.

15. The method of claim 14, wherein the thermal process is carried out by a rapid thermal process at a temperature ranging from about 800° C. to about 950° C. or by an electro-furnace process at a temperature ranging from about 700° C. to about 800° C.

16. The method of claim 13, wherein the first gate insulating layer is an Al₂O₃ layer.

17. The method of claim 13, wherein the second gate insulating layer is using a LiₓTa₁₋ₓO₃ layer, wherein x ranges from about 0.2 to about 0.8.

18. A method of manufacturing a capacitor comprising:
a) forming a first electrode;
b) forming a first dielectric layer comprising aluminum on the first electrode;
c) forming a second dielectric layer comprising lithium on the first dielectric layer; and
d) forming a second electrode on the second dielectric layer.

19. The method of claim 18, further comprising the step of performing a boundary treatment process after forming the first electrode to remove a native oxide layer on the first electrode surface.

20. The method of claim 19, wherein the surface treatment process is carried out using an HF solution.

21. The method of claim 20, further comprising the step of performing a boundary treatment process by using a NH₄OH solution or a H₂SO₄ solution before or after the surface treatment process.

22. The method of claim 18, further comprising the step of performing a nitride treatment process of a surface the first gate electrode in-situ or ex-situ.

23. The method of claim 22, wherein the nitride treatment process is carried out in an atmosphere of a NH₃ gas or in an atmosphere of N₂/H₂ gas and at a temperature ranging from about 300° C. to about 500° C.

24. The method of claim 22, wherein the nitride treatment process is carried out by a rapid thermal process at a temperature ranging from about 750° C. to about 950° and in an atmosphere of a NH₃ gas for a time period ranging from about 30 seconds to about 120 seconds.

25. The method of claim 22, wherein the nitride treatment process is carried out by an electro-furnace process at a temperature ranging from about 500° C. to about 1000° C. and in an atmosphere of a NH₃ gas.

26. The method of claim 18, wherein the first dielectric layer formation process is carried out by a low pressure chemical vapor deposition process or a atomic layer deposition process with an Al₂O₃ layer.

27. The method of claim 26, wherein the low pressure chemical vapor deposition process of the Al₂O₃ layer is carried out by evaporation of an Al(OC₂H5)₃ solution adding oxygen, which a chemical vapor having aluminum is provided to a vaporizer or an evaporating tube through a flow controller, at a temperature ranging from about 150° C. to about 300° C.

28. The method of claim 18, wherein the second dielectric layer formation step is carried out by one deposition method between a LPCVD method or ALD method, and the second dielectric layer is using a LiₓTa₁₋ₓO₃ layer, wherein x ranges from about 0.2 to about 0.8.

29. The method of claim 28, wherein the LPCVD method of the LiₓTa₁₋ₓO₃ layer is carried out at a temperature ranging from about 300° C. to about 600° C. and at a pressure ranging from about 0.1 to about 5.0 torr using a chemical vapor gas and wherein the chemical vapor gas has Li and Ta compounds at a mole ratio of Ta/Li ranging from about 0.1 to about 10 and an O₂ gas flow rate ranging from about 0 sccm to about 300 sccm which are controlled by a mass flow controller (MFC).

30. The method of claim 29, wherein the Li compound in the chemical vapor is obtained from a saturated or over-saturated alcohol or deionized liquid of C₂H₃LiO₂, LiOH or Li₂O at a temperature ranging from about 100° C. to about 400° C. through a mass flow controller (MFC).

31. The method of claim 29, wherein the Ta compound is generated by evaporating an organic metal compound having Ta(OC₂H₅)₅ or Ta(N(CH₃)₂)₅ of over 99.999% at a temperature ranging from about 150° C. to about 200° C. and wherein, in order to prevent a condensation of the vapor gas, the Ta compound is injected to a LPCVD chamber maintained at a temperature ranging from about 150° C. to about 200° C. and at a pressure ranging from about 0.1 torr to about 5 torr.

32. A method of manufacturing a capacitor comprising:
a) forming a first electrode;
b) forming a uneven surface on the first electrode;
c) nitrating the uneven surface of the first electrode;
d) forming an Al₂O₃ layer on the first electrode;
e) applying a thermal process to the Al₂O₃ layer;
f) forming LiₓTa₁₋ₓO₃ layer, wherein x ranges from about 0.2 to about 0.8 on the thermal processed Al₂O₃ layer;
g) applying a thermal process to the LiₓTa₁₋ₓO₃ layer; and
h) forming a second electrode on the thermal processed LiₓTa₁₋ₓO₃ layer.

33. The method of claim 32, wherein the thermal treatment of the Al₂O₃ layer and the LiₓTa₁₋ₓO₃ layer is carried out at one thermal treatment device selected between a rapid thermal process (RTP) device maintaining a first temperature ranging from about 800° C. to about 950° and an electro-furnace maintaining a second temperature ranging from about 700° C. to 800° C. and the rapid thermal process (RTP) and the electro-furnace in an atmosphere of N₂O, N₂ or N₂/O₂ gas.
